(19) United States
(12) Patent Application Publication
(10) Pub. No.: US 2026/0309823 A1
(43) Pub. Date: Oct. 8, 2026

(54) Rigid Body Motion and Background Phase Correction Using GRAPPA Aided Motion Transformed Coil Sensitivity Maps

(71) Applicant: The Board of Trustees of the Leland Stanford Junior University, Stanford, CA (US)

(72) Inventors: Kawin Setsompop, Stanford, CA (US); Nan Wang, Redwood City, CA (US); Daniel Raz Abraham, Palo Alto, CA (US); Yimeng Lin, Stanford, CA (US)

(21) Appl. No.: 19/566,970

(22) Filed: Mar. 13, 2026

Related U.S. Application Data
(60) Provisional application No. 63/772,131, filed on Mar. 14, 2025.

(51) Int. Cl. G01R 33/565; G01R 33/48; G01R 33/58

(52) U.S. Cl. CPC G01R 33/56509; G01R 33/4822; G01R 33/4826; G01R 33/58

(57) ABSTRACT

A method for MRI performs motion-corrected reconstruction using a one-time k-space processing step followed by efficient parallel reconstruction using a simple forward model operator. Local kernel operators are generated and applied to motion-corrupted k-space data to produced clean k-space data. Images are then efficiently reconstructed from the cleaned k-space data. This motion-corrected MRI reconstruction technique incorporates many motion states per acquisition from high-temporal-resolution tracking. It jointly corrects trajectory perturbations, coil reweighting, and δB₀-induced phase changes, enabling fast, high-quality reconstruction of strongly motion-corrupted data.

### CROSS-REFERENCE TO RELATED APPLICATIONS

This application claims priority from U.S. Provisional Patent Application 63/772,131 filed Mar. 14, 2025, which is incorporated herein by reference.

### STATEMENT REGARDING FEDERALLY SPONSORED RESEARCH OR DEVELOPMENT

This invention was made with Government support under contracts EB019437, EB033206, and MH116173 awarded by the National Institutes of Health. The Government has certain rights in the invention.

### FIELD OF THE INVENTION

The invention relates generally to magnetic resonance imaging. More specifically, it relates to methods for mitigating imaging artifacts induced by motion and/or phase perturbations.

### BACKGROUND OF THE INVENTION

Magnetic resonance imaging (MRI) often requires long acquisition times, during which subject motion and polarizing magnetic field perturbations (δB₀) can occur, leading to significant image artifacts. In particular, motion during an MRI acquisition simultaneously (i) perturbs k-space sampling locations (ii) alters relative coil-sensitivity weighting, and (iii) induces spatially varying polarizing magnetic field perturbations (δB₀). These effects lead to ghosting, blurring, and coil-weighting-related artifacts, and are especially severe in long echo time (TE),

$${T}_{2}^{*}$$

weighted acquisitions where δB₀ produces large phase errors.

External devices and navigator-based approaches can now provide sub-second estimates of rigid-body motion and δB₀ with high precision, yielding hundreds to thousands of motion states within a single scan. Here, a motion state refers to a time interval characterized by a specific realization of acquisition imperfections, including rigid-body motion, δB₀, and potentially other field perturbations. For example, a 1-mm whole-brain 3D multi-echo gradient echo (GRE) acquisition with scout-based multi-echo navigators (SMENA) at 0.4 s temporal resolution can produce on the order of 1600 motion and δB₀ states over a 10-min scan. In principle, such dense motion information enables highly accurate reconstructions that explicitly model motion and field evolution. Existing methods for motion correction generally fall into two categories: full motion-corrected reconstruction and approximate reconstruction.

Full motion-corrected reconstruction obtains motion information and incorporates motion and background phase changes directly into the forward model for each motion state to compensate for motion effects. In practice, however, incorporating hundreds to thousands of motion states into a high-fidelity forward model is prohibitively expensive. This approach scales poorly as the number of motion states increases, resulting in lengthy reconstruction times. For example, state-resolved parallel imaging reconstruction techniques such as augmented sensitivity encoding (Augmented-SENSE) and aligned sensitivity encoding (Aligned-SENSE) can accurately incorporate motion and δB₀ phase during reconstruction, but their iterative reconstruction cost grows roughly linearly with the number of motion states. This limitation becomes particularly acute when the baseline (motion-free) reconstruction is already expensive, such as in 3D echo planar time-resolved imaging (EPTI), where explicit state-resolved motion and δB₀ modeling can push computation beyond practical limits.

More efficient approximate methods for motion correction reduce or remove explicit coil reweighting and δB₀ modeling, but their assumptions break down under larger motion, substantial pose-dependent coil reweighting, and strong susceptibility effects, especially at high field and long TE. Such approximate motion-correction methods, which often apply linear phase shifts on k-space data and rotate k-space trajectories, typically assume that coil sensitivities move with the object and ignore background phase variations. These approximations can introduce inaccuracies and artifacts, particularly in high-field imaging or cases with extensive motion.

There is thus a need for a motion-corrected reconstruction technique that maintains the accuracy of full-model corrections while operating within a runtime comparable to approximate methods.

### BRIEF SUMMARY OF THE INVENTION

Herein we present a technique for fast and accurate motion-corrected MRI reconstruction. Rather than increasing the complexity of the reconstruction forward operator with every additional motion state, in the present approach we keep the downstream reconstruction operator simple and efficient, and instead handle motion and δB₀ correction in a one-time k-space processing step. More specifically, the method involves generating local kernel operators which are then applied to motion-corrupted k-space data to produced clean k-space data in a one-time cleaning step. Images are then efficiently reconstructed from the cleaned k-space data by parallel imaging reconstruction using a singular forward model for all motion states, e.g., using standard SENSE reconstruction or more advanced reconstruction techniques without modifying their forward operators. This is an accurate, fast, and generalizable motion-corrected MRI reconstruction pipeline that remains computationally efficient when incorporating hundreds to thousands of motion states per acquisition from high-temporal-resolution tracking. This approach incorporates dense motion and δB₀ tracking into SENSE-based reconstruction with minimal time penalty, jointly correcting trajectory perturbations, coil reweighting, and δB₀-induced phase changes. It enables fast, high-quality reconstruction of strongly motion-corrupted data and can be used directly with standard SENSE as well as more advanced SENSE reconstructions with priors.

The local kernel operators are similar to kernel operators in generalized autocalibrating partial parallel acquisition (GRAPPA) that are used to synthesize missing k-space data. Our local GRAPPA operators are enhanced to clean motion-corrupted k-space data by correcting state-dependent coil reweighting and δB₀-induced phase, while simultaneously mapping the corrected data onto a prescribed Cartesian grid for efficient downstream reconstruction.

In some implementations, we jointly represent families of GRAPPA kernels using an machine learning architecture, such as a multilayer perceptron (MLP). Exploiting the smooth variation of optimal kernels across nearby k-space locations and across similar motion and δB₀ states, we train the MLP to learn a continuous family of location- and state-dependent kernels. The trained model generates kernel operators utilized to interpolate k-space data, effectively rewinding background image phase variations and aligning coil sensitivities with the subject's motion. In certain implementations, motion parameters may be clustered into groups to further enhance reconstruction accuracy in challenging imaging scenarios. For example, in high-field and extreme-motion regimes, a triggered clustering strategy with intermediate-state cleaning is used to improve conditioning and stability.

In one aspect, the invention provides a method for magnetic resonance imaging (MRI), the method comprising performing the following steps with an MRI system: acquiring calibration data; acquiring multi-channel magnetic resonance (MR) measurement data comprising k-space samples subject to time-varying imaging imperfections; measuring, during the acquiring, motion state information indicative of the time-varying imaging imperfections; generating local k-space operators; applying the local k-space operators to the multi-channel MR measurement data to generate cleaned multi-channel k-space data; and reconstructing images from the cleaned multi-channel k-space data using a selected reconstruction technique. Each local k-space operator of the local k-space operators is configured to map a neighborhood of acquired multi-channel k-space samples to an estimated multi-channel k-space sample at a corresponding target k-space location, wherein the local k-space operators are configured to mitigate at least one effect of the time-varying imaging imperfections.

The time-varying imaging imperfections may be imperfections caused by one or more of: subject motion, pose-dependent receive sensitivity reweighting, static field perturbation, eddy-current-induced phase error, and trajectory deviation.

The local k-space operators may be configured to perform one or more of: (i) mapping acquired k-space samples to the one or more target k-space locations, including by gridding or reformatting; (ii) compensating for coil reweighting during the acquiring; and (iii) compensating for phase inconsistencies induced by a field perturbation during the acquiring.

Each local k-space operator may include a linear mapping from the neighborhood of the acquired multi-channel k-space samples to the estimated multi-channel k-space sample at the corresponding target k-space location, and the neighborhood is defined by k-space offsets relative to the corresponding target k-space location.

The local k-space operators may be generated by training a neural network to learn operator weights from the calibration data by forming paired training examples, the paired training examples comprising: (i) motion- and δB₀-free multi-channel calibration targets; and (ii) corrupted multi-channel calibration neighborhoods, wherein the neural network maps the corrupted multi-channel calibration neighborhoods to the motion- and δB₀-free multi-channel calibration targets. The corrupted multi-channel calibration neighborhoods may be generated by simulating, in k-space or image space, at least one of: coil reweighting, phase evolution due to field perturbation, and trajectory perturbation.

The local k-space operators may be generated by evaluating a parameterized model that outputs operator weights as a function of (i) the motion state information and (ii) neighborhood k-space offsets, thereby avoiding storing a separate operator for each time interval and each target k-space location. The parameterized model may include a neural network, and the motion state information may include at least one of: motion features and coefficients of a basis expansion representing a field perturbation. The motion features may include parameters representing rigid-body motion, including at least one of: a six-degree-of-freedom representation, a quaternion-based representation, a rotation-matrix representation, and an axis-angle representation. The basis expansion may include one or more of spherical harmonics and polynomial basis functions.

The method may include partitioning acquired k-space data into clusters based on the motion state information and determining cluster-specific local k-space operators, wherein the partitioning is triggered when a measure of state variation exceeds a threshold.

The selected reconstruction technique may include one or more of: sensitivity-encoded reconstruction, GRAPPA-based reconstruction, compressed sensing reconstruction, model-based iterative reconstruction, and reconstruction with a learned prior or denoiser.

The motion state information may be measured by one or more of: acquiring navigator data with the MRI system, receiving external tracking data, and estimating the motion state information from the multi-channel MR measurement data.

In another aspect, the invention provides a method for magnetic resonance imaging (MRI) of a subject, the method comprising: acquiring calibration data to establish initial coil sensitivity maps for a plurality of radiofrequency coils; acquiring raw k-space data from the subject using an MRI scanner, wherein the raw k-space data is associated with a plurality of motion states of the subject during acquisition; estimating motion parameters and background phase variations for each of the plurality of motion states from the acquired data; generating a plurality of interpolation kernels by training a machine learning model to learn relationships in k-space introduced by the motion parameters and background phase variations; applying the plurality of interpolation kernels to the raw k-space data to produce a cleaned k-space dataset, wherein applying the kernels aligns coil sensitivities with subject motion and rewinds background phase variations; and reconstructing an image from the cleaned k-space dataset using an iterative parallel imaging reconstruction algorithm, wherein a singular forward model transformation is performed for the plurality of motion states during each iteration.

The machine learning model may include a multilayer perceptron (MLP). Training the MLP may include extracting feature vectors representing direction vectors from k-space sampling points to target points within a defined kernel size based on a k-space trajectory and the estimated motion parameters.

The raw k-space data may be acquired using a non-Cartesian sampling trajectory, such as a spiral trajectory or a 3D spiral-projection trajectory.

The background phase variations may be induced by magnetic field (B₀) inhomogeneities associated with the plurality of motion states.

The method may further include clustering the plurality of motion states into a plurality of groups and applying the interpolation kernels to each group based on an average motion and phase calculated for said group.

The plurality of interpolation kernels may be GRAPPA-based kernels configured to compensate for coil sensitivity weighting mismatches across the plurality of motion states.

The singular forward model transformation may include a single Fast Fourier Transform (FFT) or Non-Uniform Fast Fourier Transform (NUFFT) operation for all motion states per reconstruction iteration.

### BRIEF DESCRIPTION OF THE SEVERAL VIEWS OF THE DRAWINGS

FIG. 1 is a flowchart illustrating an MRI imaging process, according to one embodiment of the invention.

FIG. 2 illustrates how local-GRAPPA operators act on motion-corrupted k-space data to create clean data for direct use with standard-SENSE, according to one embodiment of the invention.

FIG. 3 illustrates a multilayer-perception (MLP) [symbol] _{θ}parameterized by weights θ trained for efficient GRAPPA kernel generation and compact storage, according to one embodiment of the invention.

FIG. 4 illustrates the calibration pairs used for training the MLP, according to one embodiment of the invention.

### DETAILED DESCRIPTION OF THE INVENTION

The following description pertains to a method for MRI using a technique for rapidly reconstructing MRI data corrupted by subject motion and background phase changes, bridging the performance gap between fast approximate corrections and slow full-model reconstructions. The core of the technique is the generation of local kernel operators which are applied to raw k-space data to compensate for motion and phase perturbations induced artifacts. The cleaned k-space data is then used in efficient parallel imaging reconstruction.

### System Overview and Pipeline

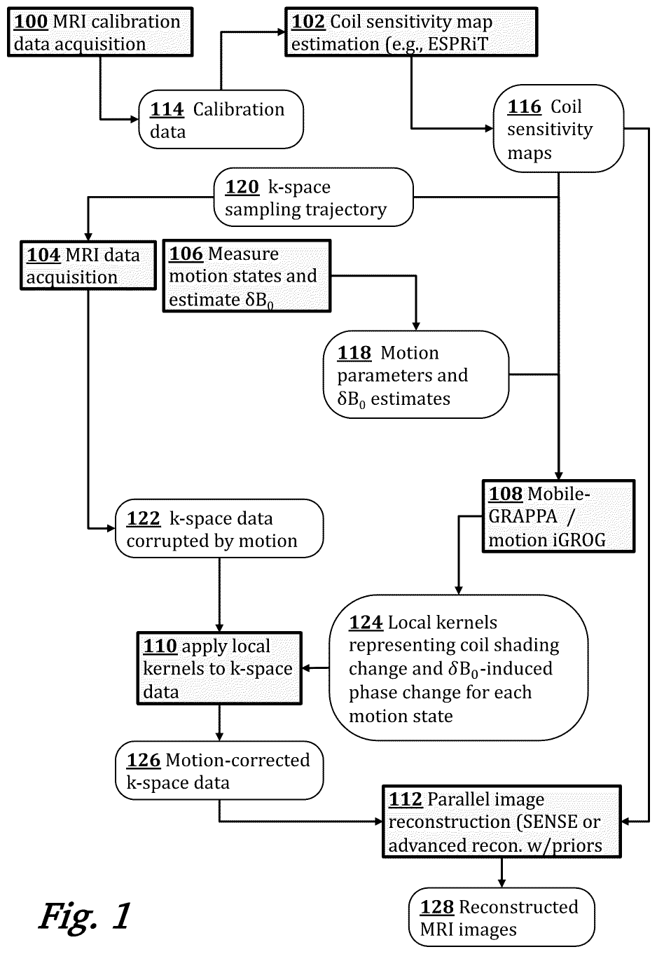

FIG. 1 is a flowchart illustrating an MRI imaging process, according to one embodiment of the invention. In step 100, low-resolution calibration data 114 is acquired in a pre-scan.

In step 102, coil sensitivity maps 116 are estimated from the calibration data 114 using a standard technique, such as ESPIRiT. In step 104, an MRI data acquisition is performed using a Cartesian or non-Cartesian k-space sampling trajectory 120, producing raw k-space data 122 that is corrupted by motion of the subject and/or phase perturbation during the acquisition. Concurrently with the data acquisition 104, motion and associated δB₀ estimation is performed in step 106 to produce motion parameters and δB₀ estimates 118. For non-Cartesian sampling trajectories, such as spiral or 3D spiral-projection imaging, this step may also include calculating density compensation. In step 108, the estimated coil sensitivity maps 116, the k-space sampling trajectory 120, and the motion parameters and δB₀ estimates 118 are used to produce local kernel operators 124 that represent coil weighting changes and δB₀-induced phase changes for each motion state. In step 110, the local kernel operators 124 are applied to the raw k-space data 122 that is corrupted by motion, producing clean, motion-corrected k-space data 126. In step 112, a parallel imaging reconstruction technique (e.g, SENSE or advanced reconstruction with priors) is used to produce reconstructed MRI images 128 from the clean, motion-corrected k-space data 126.

In a preferred embodiment, step 108—which we call mobile-GRAPPA or motion iGROG—employs a trained machine learning model to generate GRAPPA-based kernels 124 that represent coil weighting changes and δB₀ induced phase changes in k-space. Once the k-space data 122 is cleaned by these kernels 124 to produce motion-corrected k-space data 126, a standard parallel imaging reconstruction 112 produces the MRI images 128 which are free of motion artifacts. In implementations in which the kernels also map the data onto a Cartesian grid, the reconstruction may use fast Fourier transformations (FFTs) operations. In implementations in which the kernels perform correction without gridding, the reconstruction may use non-uniform FFTs (NUFFTs) operations. In either case, the correction is performed as a preprocessing step, such that FFT or NUFFT operations are performed only once for all motion states during each reconstruction iteration, rather than separately for each motion state.

In some embodiments, the machine learning model is a multilayer perceptron (MLP).

Training of the MLP includes forming source-target training pairs from calibration data, constructing feature vectors, and learning local kernel operators. For each motion state and selected k-space sample location, neighboring source samples are selected from a local k-space neighborhood around that sample location, wherein the source samples comprise k-space data generated from calibration data to represent the coil weighting and δB₀-induced phase associated with that motion state. A corresponding target is also selected, the target being selected from acquired coil-sensitivity calibration data to provide a motion- and δB₀-free k-space reference. In some implementations, the target is defined at a non-Cartesian sample location, so that the learned kernel performs data cleaning without gridding. In other implementations, the target is defined at a Cartesian grid location, so that the learned kernel performs data cleaning and gridding together. The feature vectors include motion-state features and relative positional offsets between the neighboring source sample locations and the target location. The motion features may include parameters representing rigid-body motion, such as one or more of a six-degree-of-freedom representation, a quaternion-based representation, a rotation-matrix representation, and an axis-angle representation. For the MLP training, the MLP architecture may include an input layer for the feature vectors, one or more hidden layers, and an output layer that generates kernel coefficients configured to transform the source data into corrected target data by compensating for coil weighting changes and δB₀-induced phase changes and, in some implementations, also performing gridding. The MLP is trained by minimizing a loss between predicted target data and calibration target data.

### Technical Details and Comparison

In this section, we first present two existing state-resolved parallel imaging reconstruction techniques, augmented sensitivity encoding (Augmented-SENSE) and aligned sensitivity encoding (Aligned-SENSE). We first review Augmented-SENSE and its commonly used approximation, highlighting the trade-off between model fidelity and computational efficiency. We then review Aligned-SENSE, which provides a complementary image-domain formulation with the same accuracy and unfavorable scaling with the number of motion states. We then introduce the present technique, which achieves high image quality with low computational cost by performing a one-time k-space cleaning step prior to reconstruction. We also describe an MLP-based representation of Mobile-GRAPPA kernels that exploits smooth kernel weights across motion, δB₀, and k-space location.

### Augmented-SENSE

We denote the complex transverse magnetization in a reference pose by x(r) and the coil sensitivity maps in the same coordinate system by S(r). The acquisition is partitioned into rigid-body motion states indexed by n=1, . . . , Nₛₜₐₜₑ, where state n is characterized by a rigid transform Tₙ with rotation Rₙ and translation cₙ. When available, each state also has an associated image phase φₙ(r, t) induced by δB₀. We denote the measured multi-coil signal by yₙ(t) and the nominal trajectory sample by kₙ(t).

Augmented-SENSE accounts for rigid motion by transforming the sampling locations and the coil sensitivities. First, the trajectory is inverse-rotated:

$${\tilde{k}}_{n} ( t ) = {R}_{n}^{- 1} {k}_{n} ( t ) , n \qquad ( 1 )$$

which is generally not on the Cartesian grid. Therefore, Augmented-SENSE typically requires non-uniform Fourier transform (NUFFT) to model the Fourier encoding on \tilde{k}ₙ(t), even when the underlying acquisition was originally Cartesian.

Second, translations are modeled as a linear phase applied to the measured signal:

$${\tilde{y}}_{n} ( t ) = {y}_{n} ( t ) {e}^{i 2 π {k}_{n} ( t ) \cdot {c}_{n}} \qquad ( 2 )$$

Third, coil sensitivities are inverse-transformed into the pose of each state:

$${\tilde{S}}_{n} ( r ) = {T}_{n}^{- 1} [ S ( r ) ] . \qquad ( 3 )$$

With these definitions, the Augmented-SENSE signal model becomes

$${\tilde{y}}_{n} ( t ) = \int [ x ( r ) {e}^{i {ϕ}_{n} ( r , t )} ] {\tilde{S}}_{n} ( r ) {e}^{- i 2 π {\tilde{k}}_{n} ( t ) \cdot r} dr . \qquad ( 4 )$$

In operator form, let \tilde{F} denote the NUFFT operator. Let \tilde{Ω}ₙ denote the sampling operator for motion state n after inverse rotation, corresponding to sampling on \tilde{k}ₙ(t). Let \tilde{S} denote the coil sensitivity operator formed from the inverse-transformed coil maps. Let Pₙ denote the image-domain phase modulation induced by δB₀ during state n. The state n encoding operator is

$${\tilde{E}}_{n} = {\tilde{Ω}}_{n} \tilde{F} {\tilde{S}}_{n} {P}_{n} , \qquad ( 5 )$$

and Augmented-SENSE estimates the image x from k-space data \tilde{y}ₙ by solving

$$\hat{x} = \frac{1}{2} arg {min}_{x} {\sum }_{n = 1}^{{N}_{state}} {‖ {\tilde{E}}_{n} x - {\tilde{y}}_{n} ‖}_{2}^{2} + λℛ ( x ) , \qquad ( 6 )$$

where λ≥0 controls the strength of regularization and [symbol] (⋅) is a chosen image regularizer such as Tikhonov or a learned prior.

Iterative solvers require repeated application of all \tilde{E}ₙ and

$${\tilde{E}}_{n}^{H} ,$$

so the per-iteration arithmetic cost scales approximately linearly with Nₛₜₐₜₑ. Moreover, storing and regenerating the state-dependent components increases memory usage, so practical runtime can exceed the ideal linear scaling.

### Approximate Augmented-SENSE

To reduce computational burden, Approximate Augmented-SENSE (Approx-Aug-SENSE) retains only the trajectory inverse-rotation and the translation phase term, while dropping explicit coil transformations and detailed δB₀ modeling. Under these approximations, \tilde{S}ₙ(r) is replaced by a single reference sensitivity map S(r), and the phase term e^{iφ}^{ₙ}^{(r,t)} is neglected:

$${\tilde{y}}_{n} ( t ) \approx \int x ( r ) S ( r ) {e}^{- i 2 π {\tilde{k}}_{n} ( t ) \cdot r} dr . \qquad ( 7 )$$

Equivalently, all motion states share a single encoding operator

$$\tilde{E} = \tilde{Ω} \tilde{F} S , \qquad ( 8 )$$

and reconstruction solves

$$\hat{x} = \frac{1}{2} arg {min}_{x} {‖ \tilde{E} x - \tilde{y} ‖}_{2}^{2} + λ ℛ ( x ) \qquad ( 9 )$$

with \tilde{Ω} aggregating the inverse-rotated sampling locations and \tilde{y} aggregating the measured signals with linear translation phase applied. So the per-iteration cost no longer scales with the number of states. This efficiency, however, relies on the assumptions that state-dependent coil reweighting and δB₀-induced phase are negligible. These assumptions can break down under large motion, strong coil variation, and pronounced susceptibility effects, particularly at high field and long TE.

### Aligned-SENSE

Aligned-SENSE provides a complementary formulation that emphasizes image-domain motion modeling. Using the same notation as above, the measured signal for motion state n at readout time t is

$${y}_{n} ( t ) = \int S ( r ) {T}_{n} [ x ( r ) {e}^{i {ϕ}_{n} ( r , t )} ] {e}^{- i 2 π {k}_{n} ( t ) \cdot r} dr . \qquad ( 10 )$$

Aligned-SENSE is particularly convenient for Cartesian acquisitions because it does not require trajectory modification and thus preserves FFT-based encoding on the nominal grid, avoiding the NUFFT that arises in Augmented-SENSE after inverse-rotating k-space samples. In operator form, let F denote the FFT, Ωₙ the nominal sampling mask for state n. The state-n encoding operator is

$${E}_{n} = {Ω}_{n} F S {T}_{n} {P}_{n} , \qquad ( 11 )$$

and reconstruction solves

$$\hat{x} = \frac{1}{2} arg {min}_{x} {\sum }_{n = 1}^{{N}_{s t a t e}} {‖ {E}_{n} x - {y}_{n} ‖}_{2}^{2} + λ ℛ ( x ) . \qquad ( 12 )$$

As in Augmented-SENSE, iterative solvers require repeated application of every Eₙ and

$${E}_{n}^{H} ,$$

and the per-iteration cost becomes prohibitive when hundreds to thousands of states are present.

### Present Technique: Mobile-GRAPPA

In contrast with the existing techniques described above, the present technique provides a generalizable reconstruction pipeline for motion-corrupted data that maintains high accuracy with minimal additional runtime. In this embodiment we adapt the Approx-Aug-SENSE forward model, which achieves favorable computational scaling, but whose simplifying assumptions create a mismatch between the forward model and the acquired k-space data. Our technique uses a k-space processing step that removes this mismatch in a one-time step so that the subsequent reconstruction can remain fast and unchanged.

The present technique, referred to here as Mobile-GRAPPA, performs a one-time correction on the measured data with two coupled functions: (i) it reduces the mismatch between Approx-Aug-SENSE and the acquired data by correcting state-dependent coil reweighting and δB₀-induced image phase; and (ii) it replaces expensive NUFFT operations with FFTs by mapping the corrected data onto the prescribed R₁ Cartesian grid.

In Mobile-GRAPPA, \tilde{y}_{clean}=G\tilde{y} is the clean k-space data obtained by applying a family of local kernels G={G_{n,k}_{₀}} to the measured k-space data \tilde{y} to perform gridding and correct coil reweighting and δB₀-induced image phase. The reconstruction solves

$$\hat{x} = \frac{1}{2} arg {min}_{x} {‖ {\tilde{Ω}}_{g r i d} F S x - {\tilde{y}}_{c l e a n} ‖}_{2}^{2} + λ ℛ ( x ) . \qquad ( 13 )$$

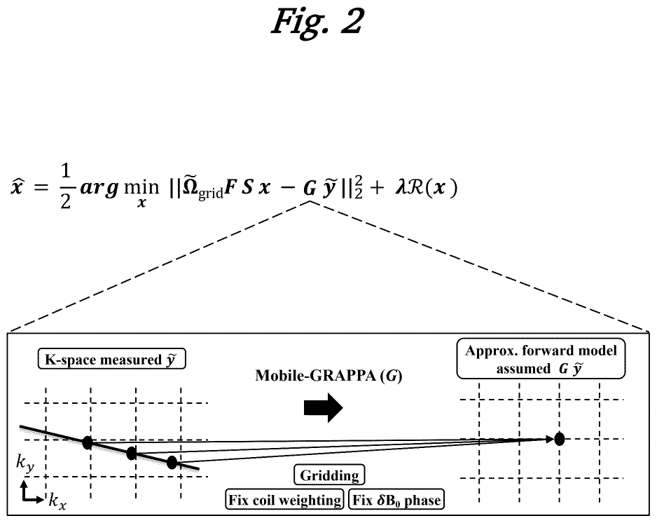

FIG. 2 illustrates how local-GRAPPA operators G act on motion-corrupted k-space data \tilde{y} to simultaneously perform k-space gridding and remove δB₀-induced phase and coil reweighting, creating clean data \tilde{y}_{clean}=G\tilde{y} for direct use with standard-SENSE. Each motion state and each k-space location has its own local GRAPPA kernel.

Operationally, for each motion state we first apply the standard Approx-Aug-SENSE preprocessing: inverse-rotate the trajectory and apply the translation phase on k-space. Let k₀ denote a sample location on the inverse-rotated trajectory. We define k_{0,grid} as the nearest point to k₀ on the prescribed R₁ Cartesian grid. Mobile-GRAPPA then uses a local neighborhood of multichannel samples around k₀ to produce a cleaned estimate at k_{0,grid}. Aggregating these cleaned estimates across all motion states yields a cleaned dataset on the R₁ Cartesian grid. The cleaned data can then be used as input to image reconstruction using standard SENSE, or used as input to more advanced reconstructions with priors, without explicitly modifying the forward operator to incorporate motion or δB₀-induced image phase.

### Mobile-GRAPPA Training Process and MLP Architecture

This subsection details the Mobile-GRAPPA processing technique. Mobile-GRAPPA is trained using low-resolution calibration data and then applied once to the motion-corrupted data to generate cleaned k-space on the R₁Cartesian grid.

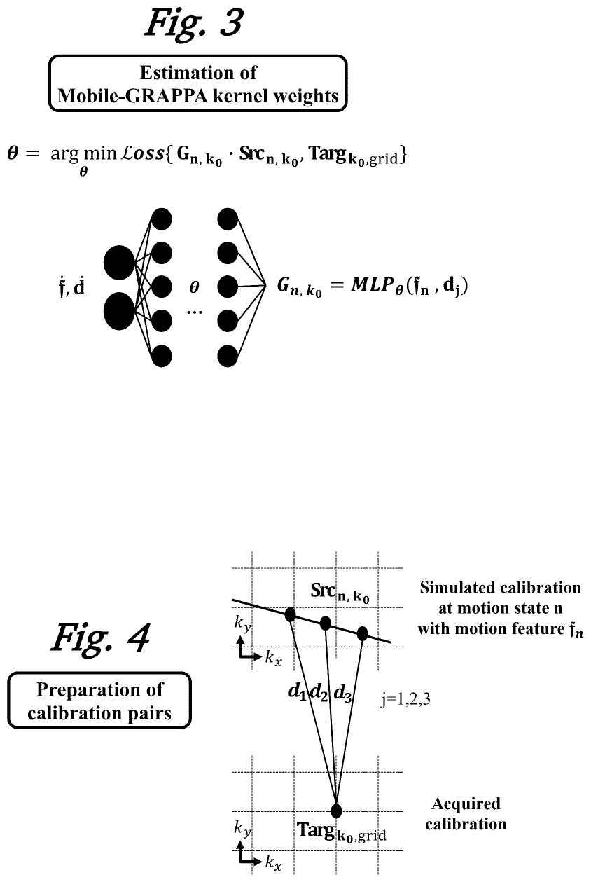

FIG. 3 illustrates a multilayer-perception (MLP) [symbol] [symbol] [symbol] _{θ} parameterized by weights θ for efficient GRAPPA kernel training and compact storage. We efficiently train the MLP to learn a family of Mobile-GRAPPA kernels G={G_{n,k}_{₀}} jointly using coil-sensitivity calibration data simulated to be corrupted across a range of motions and δB₀-induced image phases. The MLP takes motion- and δB₀-information and source k-space positions relative to the target gridded point as inputs, passes these along three hidden layers, and outputs a cleaning set of GRAPPA kernels specific for the input conditions.

For each motion state we form training examples indexed by inverse-rotated trajectory samples k₀ with associated target grid locations k_{0,grid}. To form a source neighborhood for k₀, we select the J nearest samples to k₀ along the readout dimension on the same readout line and denote their locations by

$${\{ {k}_{j} \}}_{j = 1}^{J} .$$

Using fully sampled low-resolution calibration data, we extract the clean target at the corresponding grid location, denoted by Targₖ_{_{0,grid}}. Using rigid-body motion parameters and shot-to-shot δB₀ estimates, we simulate the motion- and δB₀-corrupted calibration measurements for each motion state and extract the corresponding source vectors Src_{n,k}_{₀}. This yields paired calibration examples (Src_{n,k}_{₀}, Targₖ_{_{0,grid}}). FIG. 4 illustrates these calibration pairs used for training the MLP.

For each motion state and trajectory sample k₀, we define a Mobile-GRAPPA kernel G_{n,k}_{₀} that maps the source neighborhood to the cleaned target at k_{0,grid}:

$${Targ}_{{k}_{0 , grid}} = {G}_{n , {k}_{0}} {Src}_{n , {k}_{0}} , \qquad ( 14 )$$

so G_{n,k}_{₀} maps from (J·N_{coil}) inputs to N_{coil} outputs.

A naive implementation would estimate and store a distinct kernel G_{n,k}_{₀} for every motion state and every trajectory sample, which is expensive because the kernels are both motion-state-specific and sample-location-specific. In practice, kernel weights are strongly correlated across similar poses and nearby k-space locations. We therefore represent the kernel family compactly using an MLP.

We learn {G_{n,k}_{₀}} using an MLP trained on the calibration pairs. The MLP takes motion-and-δB₀ features fₙ and relative source-to-target offsets dⱼ=kⱼ−k₀ as inputs and outputs the kernel weights:

$${G}_{n , {k}_{0}} = ℳ ℒ {𝒫}_{θ} ( {f}_{n} , \{ {d}_{j} \} ) , \qquad ( 15 )$$

where θ are network parameters.

Rather than providing full δB₀ maps to the network, we preferably represent state-dependent δB₀ using the spherical-harmonic expansion and use the fitted coefficients as features. This spherical-harmonic fitting provides a compact approximation to smoothly varying field perturbations while avoiding high-dimensional image-domain inputs. For the 3T and 7T brain experiments, second-order spherical harmonics are sufficient for stable training and reliable generalization. Alternatively, polynomial basis functions may be used to represent state-dependent δB₀.

During training, we stochastically sample trajectory locations k₀ and motion states n. We use an [symbol] data term to measure mismatch between Mobile-GRAPPA cleaned k-space and the clean target, and optionally add [symbol] regularization on kernel weights:

$$ℒ 𝒪 𝒮 𝒮 \{ {G}_{n , {k}_{0}} {Src}_{n , {k}_{0}} , {Targ}_{{k}_{0 , grid}} \} = {\sum }_{n , {k}_{0}} {‖ {G}_{n , {k}_{0}} {Src}_{n , {k}_{0}} , {Targ}_{{k}_{0 , grid}} ‖}_{1} + λ {‖ {G}_{n , {k}_{0}} ‖}_{2}^{2} , \qquad ( 16 )$$

$$θ = arg {min}_{θ} ℒ 𝒪 𝒮 𝒮 \{ {G}_{n , {k}_{0}} {Src}_{n , {k}_{0}} , {Targ}_{{k}_{0 , grid}} \} . \qquad ( 17 )$$

In practice, the MLP converges quickly, with typical training times<10 s per volume.

After training, we query the MLP with motion-and-δB₀ features fₙ and relative source-to-target offsets {dⱼ} for each trajectory sample k₀ in the acquired motion-corrupted data to obtain G_{n,k}_{₀}. We then apply Eq. (14) to produce cleaned estimates at k_{0,grid}. When multiple k₀ map to the same k_{0,grid}, we aggregate the corresponding estimates to form the final cleaned k-space on the R₁ Cartesian grid.

### Triggered Motion Clustering and Intermediate-State Cleaning for Extreme Motion

In more challenging scenarios, such as extreme motion regimes where coil weighting and δB₀-induced phase variations are more complex, the technique may incorporate motion clustering. In these implementations, motion parameters are clustered into groups. The technique is applied to each group targeting the intermediate state, like average motion and phase of that group, and each group is then incorporated separately into the forward model.

This approach has been shown to improve reconstruction performance to near full-correction levels with only a minimal increase in reconstruction time. This clustering improves mobile-GRAPPA's robustness to large motions and field variations, when motions are very large (>10 degree). The motion-clustering constrains each kernel set to operate over smaller effective motion and δB₀ variation range, making interpolation more reliable, with reconstruction time scaling linearly as the number of clusters used. The intermediate state m encoding operator is:

$${\tilde{E}}_{m} = {\tilde{Ω}}_{grid , m} F {\tilde{S}}_{m} {P}_{m} , \qquad ( 18 )$$

and the reconstruction solves:

$$\hat{x} = \frac{1}{2} arg {min}_{x} {\sum }_{m = 1}^{{N}_{c}} {‖ {\tilde{E}}_{m} x - {G}_{m} {\tilde{y}}_{m} ‖}_{2}^{2} + λ ℛ ( x ) . \qquad ( 19 )$$

For moderate motion ranges, a single MLP can model kernel variation across all motion and δB₀states. In extreme-motion regimes or under strong pose-dependent coil-sensitivity variation, performance can degrade for two complementary reasons. First, the mapping from motion-and-δB₀features to optimal kernel weights can vary more rapidly across a large pose range, reducing interpolation reliability for a single MLP. Second, and often more limiting, the required one-step k-space cleaning can become poorly conditioned: when the coil encoding is insufficiently informative for the correction implied by large motion or strong δB₀, the learned linear operator may amplify noise, analogous to noise amplification in ill-conditioned parallel imaging inversions.

To improve stability, we reduce the required correction per application by cleaning each acquired state to a nearby intermediate state rather than directly to the motion- and δB₀-free state. We trigger clustering when the maximal rotation across states exceeds a threshold. Motion states are clustered in rigid-body parameter space, and each cluster m∈{1, . . . , N_{c}} is assigned a representative transform T. (e.g., a centroid pose). For each cluster, we train a cluster-specific MLP that predicts kernels using relative motion to the intermediate pose and the corresponding δB₀features.

The intermediate-state cleaning operation produces a cleaned estimate on the R₁ grid consistent with the intermediate pose:

$${Targ}_{m , {k}_{0 , grid}} = {G}_{n \to m , {k}_{0}} {Src}_{n , {k}_{0}} , \qquad ( 20 )$$

where Targ_{m,k}_{_{0,grid}} denotes the desired sample at k_{0,grid} with coil weighting and background phase referenced to intermediate pose m.

After cleaning, we aggregate samples within each intermediate state to form N_{c} gridded datasets and perform reconstruction using a small set of discrete states rather than the full set of original motion states. This strategy avoids overly aggressive single-step corrections, improves conditioning, and maintains low overhead compared with fully state-resolved formulations such as Aligned-SENSE. In this regime, Mobile-GRAPPA scales primarily with the number of intermediate states, while remaining largely independent of N^{state} in the downstream reconstruction.

### Discussion

Mobile-GRAPPA reconciles dense motion and δB₀ tracking with feasible reconstruction times. Instead of embedding every motion state directly into forward operator, Mobile-GRAPPA operates in k-space: it uses local GRAPPA operators to map motion- and δB₀-corrupted data to clean k-space data, after which reconstruction proceeds with standard SENSE or other advanced pipeline. In this way, motion and δB₀ modeling is decoupled from the image-space iterative solve.

Across characterization and generalized application, Mobile-GRAPPA consistently achieves artifact suppression comparable to full Aligned-SENSE while remaining computationally efficient. It reduces ringing, ghosting, and blurring in heavily motion-corrupted 3D multi-echo GRE at 3T, stabilizes EPTI under both heavy motion and deep breathing, and remains robust at 7T where δB₀ and coil variation are stronger. Relative to Approx-Aug-SENSE, Mobile-GRAPPA adds learned corrections for coil reweighting and δB₀-induced phase. Importantly, these corrections can be applied separately or jointly depending on the dominant error source: for short-TE scans, δB₀phase may be secondary, whereas for minimal-motion deep-breathing cases, δB₀-induced phase changes can dominate.

Mobile-GRAPPA also changes the scaling behavior of motion and δB₀ modeling. In Aligned-SENSE and Augmented-SENSE, cost grows roughly linearly with the number of motion states because each state contributes a distinct encoding operator that must be applied in every iteration. In contrast, Mobile-GRAPPA adds a small, nearly constant overhead: brief MLP training (seconds per volume) and a ~1 s k-space application step, after which reconstruction proceeds at the no-motion baseline complexity. When clustering is triggered for very large motions, runtime scales with the number of clusters rather than the number of states, and the required number of clusters in practice is modest. Among all the experiments, we at most needed 2 cluster to achieve comparable result to Aligned-SENSE.

An additional benefit is that Mobile-GRAPPA preserves, rather than compresses, temporal information. Conventional strategies for large numbers of motion states rely on temporal down-sampling or coarse clustering, which discards fine temporal structure in motion and δB₀ traces. Mobile-GRAPPA uses all states during training and application: temporal variation is captured by the learned kernel family, which is queried for each state individually. Thus, tractability is achieved without sacrificing temporal resolution.

The MLP-based representation of a kernel family is not limited to motion correction. More broadly, it provides a mechanism for representing smoothly varying image-domain imperfections as local k-space operators. For example, eddy-current-induced phase, which is often spatially smooth, may also be amenable to correction via learned local kernels. However, Mobile-GRAPPA should not be expected to directly model highly complex, high-spatial-frequency B₀ structure: high order B₀ spread energy broadly in k-space and are less likely to be learned stably by strictly local kernels.

Mobile-GRAPPA is naturally compatible with a wide range of reconstruction strategies. Because the cleaned k-space data can be used with conventional conjugate gradient (CG) SENSE, spatiotemporal subspace reconstructions such as EPTI, or formulations incorporating learned priors and plug-in regularizes. In each case, the data-consistency operator remains unchanged because Mobile-GRAPPA modifies only the input k-space data.

If the motion and δB₀ estimation is inaccurate, the mobile-GRAPPA-based cleaning step will leave residual inconsistencies in k-space. GRAPPA-style reconstructions can be more robust than SENSE under model mismatch because GRAPPA applies localized constraints, whereas SENSE enforces global unaliasing that can amplify structured errors when the forward model is wrong. This observation suggests a natural extension: Mobile-GRAPPA-cleaned data could also be used as input to GRAPPA-based image reconstruction when robustness to estimation error is paramount.

### CONCLUSIONS

Mobile-GRAPPA is a motion- and δB₀-aware k-space cleaning framework that uses local GRAPPA kernels to map motion- and δB₀-corrupted k-space data to a motion- and δB₀-free state. This one-time operation performs effective trajectory gridding, coil reweighting correction, and δB₀ phase correction, enabling dense motion and δB₀modeling with nearly constant reconstruction time. The cleaned k-space data can be reconstructed using standard SENSE, subspace methods, or other pipelines without modifying their forward operators. Across characterization and in vivo experiments at 3T and 7T, Mobile-GRAPPA achieves image quality comparable to Aligned-SENSE without significant noise amplification and with reconstruction times close to no-motion baselines.

1. A method for magnetic resonance imaging (MRI), the method comprising performing the following steps with an MRI system:
(a) acquiring calibration data;
(b) acquiring multi-channel magnetic resonance (MR) measurement data comprising k-space samples subject to time-varying imaging imperfections;
(c) measuring, during the acquiring, motion state information indicative of the time-varying imaging imperfections;
(d) generating local k-space operators, wherein each local k-space operator of the local k-space operators is configured to map a neighborhood of acquired multi-channel k-space samples to an estimated multi-channel k-space sample at a corresponding target k-space location, wherein the local k-space operators are configured to mitigate at least one effect of the time-varying imaging imperfections;
(e) applying the local k-space operators to the multi-channel MR measurement data to generate cleaned multi-channel k-space data; and
(f) reconstructing images from the cleaned multi-channel k-space data using a selected reconstruction technique.

2. The method of claim 1, wherein the time-varying imaging imperfections are imperfections caused by one or more of: subject motion, pose-dependent receive sensitivity reweighting, static field perturbation, eddy-current-induced phase error, and trajectory deviation.

3. The method of claim 1, wherein the local k-space operators are configured to perform one or more of: (i) mapping acquired k-space samples to the one or more target k-space locations, including by gridding or reformatting; (ii) compensating for coil reweighting during the acquiring; and (iii) compensating for phase inconsistencies induced by a field perturbation during the acquiring.

4. The method of claim 1, wherein each local k-space operator comprises a linear mapping from the neighborhood of the acquired multi-channel k-space samples to the estimated multi-channel k-space sample at the corresponding target k-space location, and wherein the neighborhood is defined by k-space offsets relative to the corresponding target k-space location.

5. The method of claim 1, wherein generating the local k-space operators comprises training a neural network to learn operator weights from the calibration data by forming paired training examples, the paired training examples comprising: (i) motion- and δB₀-free multi-channel calibration targets; and (ii) corrupted multi-channel calibration neighborhoods, wherein the neural network maps the corrupted multi-channel calibration neighborhoods to the motion- and δB₀-free multi-channel calibration targets.

6. The method of claim 5, wherein the corrupted multi-channel calibration neighborhoods are generated by simulating, in k-space or image space, at least one of: coil reweighting, phase evolution due to field perturbation, and trajectory perturbation.

7. The method of claim 1, wherein generating the local k-space operators comprises evaluating a parameterized model that outputs operator weights as a function of (i) the motion state information and (ii) neighborhood k-space offsets, thereby avoiding storing a separate operator for each time interval and each target k-space location.

8. The method of claim 7, wherein the parameterized model comprises a neural network, and wherein the motion state information includes at least one of: motion features and coefficients of a basis expansion representing a field perturbation.

9. The method of claim 8, wherein the motion features comprise parameters representing rigid-body motion, including at least one of: a six-degree-of-freedom representation, a quaternion-based representation, a rotation-matrix representation, and an axis-angle representation.

10. The method of claim 8, wherein the basis expansion comprises one or more of spherical harmonics and polynomial basis functions.

11. The method of claim 1, further comprising partitioning acquired k-space data into clusters based on the motion state information and determining cluster-specific local k-space operators, wherein the partitioning is triggered when a measure of state variation exceeds a threshold.

12. The method of claim 1, wherein the selected reconstruction technique comprises one or more of: sensitivity-encoded reconstruction, GRAPPA-based reconstruction, compressed sensing reconstruction, model-based iterative reconstruction, and reconstruction with a learned prior or denoiser.

13. The method of claim 1, wherein measuring the motion state information comprises one or more of: acquiring navigator data with the MRI system, receiving external tracking data, and estimating the motion state information from the multi-channel MR measurement data.

14. A method for magnetic resonance imaging (MRI) of a subject, the method comprising:
(a) acquiring calibration data to establish initial coil sensitivity maps for a plurality of radiofrequency coils;
(b) acquiring raw k-space data from the subject using an MRI scanner, wherein the raw k-space data is associated with a plurality of motion states of the subject during acquisition;
(c) estimating motion parameters and background phase variations for each of the plurality of motion states from the acquired data;
(d) generating a plurality of interpolation kernels by training a machine learning model to learn relationships in k-space introduced by the motion parameters and background phase variations;
(e) applying the plurality of interpolation kernels to the raw k-space data to produce a cleaned k-space dataset, wherein applying the kernels aligns coil sensitivities with subject motion and rewinds background phase variations; and
(f) reconstructing an image from the cleaned k-space dataset using an iterative parallel imaging reconstruction algorithm, wherein a singular forward model transformation is performed for the plurality of motion states during each iteration.

15. The method of claim 14, wherein the machine learning model comprises a multilayer perceptron (MLP).

16. The method of claim 15, wherein training the MLP comprises extracting feature vectors representing direction vectors from k-space sampling points to target points within a defined kernel size based on a k-space trajectory and the estimated motion parameters.

17. The method of claim 14, wherein the background phase variations are induced by magnetic field (B₀) inhomogeneities associated with the plurality of motion states.

18. The method of claim 14, further comprising clustering the plurality of motion states into a plurality of groups and applying the interpolation kernels to each group based on an average motion and phase calculated for said group.

19. The method of claim 14, wherein the plurality of interpolation kernels are GRAPPA-based kernels configured to compensate for coil sensitivity weighting mismatches across the plurality of motion states.

20. The method of claim 14, wherein the singular forward model transformation comprises a single Fast Fourier Transform (FFT) or Non-Uniform Fast Fourier Transform (NUFFT) operation for all motion states per reconstruction iteration.
